(19) United States
(12) Patent Application Publication
(10) Pub. No.: US 2022/0077146 A1
(43) Pub. Date: Mar. 10, 2022

(54) METHOD FOR MANUFACTURING SEMICONDUCTOR STRUCTURE AND MEMORY, AND SEMICONDUCTOR STRUCTURE

(71) Applicant: CHANGXIN MEMORY TECHNOLOGIES, INC., Hefei City (CN)

(72) Inventors: Jiancheng HU, Hefei City (CN); MingHung Hsieh, Hefei City (CN)

(21) Appl. No.: 17/455,694

(22) Filed: Nov. 19, 2021

Related U.S. Application Data
(63) Continuation of application No. PCT/CN2021/092906, filed on May 10, 2021.

(30) Foreign Application Priority Data
May 22, 2020 (CN) 202010440457.X

(51) Int. Cl. H01L 27/108; H01L 21/027

(52) U.S. Cl. CPC H01L 27/1087; H01L 21/0274; H01L 27/10829

(57) ABSTRACT

The embodiments of the present application relate to the field of semiconductor technologies, and disclose a semiconductor structure manufacturing method. The method includes: forming a hard mask on a semiconductor substrate; forming a photoresist film on the hard mask; patterning the photoresist film to form a patterned photoresist layer having first openings and second openings, wherein the second openings are disposed at intervals between the first openings; etching the hard mask by taking the patterned photoresist layer as a mask to form a patterned hard mask layer having a plurality of third openings, wherein the third openings correspond to the first openings and the second openings; and etching the semiconductor substrate by taking the patterned hard mask layer as a mask to form holes along the third openings. According to this method, the manufacturing efficiency and the quality of the holes are improved simultaneously.

### CROSS-REFERENCE TO RELATED APPLICATIONS

This application is a continuation application of International Patent Application No. PCT/CN2021/092906, filed on May 10, 2021, which claims priority to Chinese Patent Application No. 202010440457.X, filed on May 22, 2020 and entitled “METHOD FOR MANUFACTURING SEMICONDUCTOR STRUCTURE AND MEMORY, AND SEMICONDUCTOR STRUCTURE”. International Patent Application No. PCT/CN2021/092906 and Chinese Patent Application No. 202010440457.X are incorporated herein by reference in their entireties.

### TECHNICAL FIELD

The present application relates to the field of semiconductor technologies, and in particular to a method for manufacturing a semiconductor structure and a memory, and a semiconductor structure.

### BACKGROUND

Semiconductor devices, such as a dynamic random access memory (DRAM) and the like, comprise a large number of refined holes which may be formed by a photolithography process. Generally, forming holes by the photolithography process comprises following steps, which includes firstly forming a first hard mask layer on a bottom hard mask, coating a photoresist film on the first hard mask layer, and forming a linear pattern along a first direction on the photoresist film and transferring the linear pattern along the first direction to the first hard mask layer. Afterwards, a second hard mask layer and a photoresist film are formed on the first hard mask layer as patterned, and a linear pattern along a second direction is formed on the photoresist film as formed later and then transferred to the second hard mask layer. Then, the second hard mask layer as patterned is further etched, and the linear pattern along the second direction is transferred to the first hard mask layer as patterned. Since hole-shape patterns may be formed due to the intersection between the linear pattern along the second direction and the linear pattern along the first direction, a patterned bottom hard mask layer having a plurality of hole-shape patterns may be thereby acquired by further performing the etching. Finally, the semiconductor substrate is etched by the patterned bottom hard mask layer to form the holes in the semiconductor substrate according to the hole-shape patterns.

However, the inventor found that the prior art has at least following problems. The current method for manufacturing holes is to form hole-shape patterns by combining two linear patterns along different directions, which requires to transfer the hard mask pattern at least twice. Thus, the process is relatively complicated and inefficient, and the quality of the holes is likely to be poor since the hard mask pattern transferring process may have process errors and generate excessive by-products.

### SUMMARY

An object of some embodiments of the present application is to provide a method for manufacturing a semiconductor structure and a memory, and a semiconductor structure to thereby improve the quality of holes and the efficiency in manufacturing the holes.

In order to solve the technical problem, the embodiments of the present application provide a semiconductor structure manufacturing method. The method comprises: forming a hard mask on a semiconductor substrate; forming a photoresist film on the hard mask; patterning the photoresist film to form a patterned photoresist layer having a plurality of first openings and a plurality of second openings, wherein the second openings are disposed at intervals among the first openings; wherein patterning the photoresist film comprises: performing a first exposure to form a first exposure area on the photoresist film, and developing the first exposure area to enable the first exposure area to have a plurality of the first openings, and performing a second exposure to form a second exposure area on the photoresist film on which the first exposure has been performed, and developing the second exposure area to enable the second exposure area to have a plurality of the second openings; etching the hard mask by taking the patterned photoresist layer as a mask to form a patterned hard mask layer having a plurality of third openings, wherein the third openings correspond to the first openings and the second openings; and etching the semiconductor substrate by taking the patterned hard mask layer as a mask to form a plurality of holes along the third openings.

With respect to the related art, the embodiments of the present application provide a semiconductor structure manufacturing method, which comprises forming a patterned photoresist layer having a large number of first openings and second openings by performing exposure and development twice. Afterwards, the first openings and the second openings of the patterned photoresist layer are transferred to the hard mask to form a patterned hard mask layer having a plurality of third openings. That is, the patterned hard mask layer can be acquired by transferring the hard mask once, and then, a large number of holes can be formed on the semiconductor substrate by taking the patterned hard mask layer as a mask. Thus, compared with the solution of transferring the hard mask twice in the related art, the present application can reduce steps of the manufacturing process and improve the efficiency in manufacturing the holes. In addition, the present application can prevent the occurrence of large process errors and generation of excessive by-products as caused by a larger number of times of hard mask transferring, thereby improving the quality of holes as manufactured.

The embodiments of the present application provide a semiconductor structure, which comprises a semiconductor substrate, a patterned hard mask layer, and a patterned photoresist layer stacked in sequence. The patterned photoresist layer has first openings and second openings and is configured to form third openings of the patterned hard mask layer. The third openings correspond to the first openings and the second openings, the first openings and the second openings are formed by performing exposure and development twice, and the second openings are disposed at intervals between the first openings. The patterned hard mask layer is configured to form holes on the semiconductor substrate, and the holes correspond to the third openings.

The embodiments of the present application provide a memory manufacturing method. The method comprises: forming a hard mask on a semiconductor substrate; forming a photoresist film on the hard mask; patterning the photoresist film to form a patterned photoresist layer having a plurality of first openings and a plurality of second openings, wherein the second openings are disposed at intervals among the first openings; wherein patterning the photoresist film comprises: performing a first exposure to form a first exposure area on the photoresist film, and developing the first exposure area to enable the first exposure area to have a plurality of the first openings, and performing a second exposure to form a second exposure area on the photoresist film on which the first exposure has been performed, and developing the second exposure area to enable the second exposure area to have a plurality of the second openings; etching the hard mask by taking the patterned photoresist layer as a mask to form a patterned hard mask layer having a plurality of third openings, wherein the third openings correspond to the first openings and the second openings; etching the semiconductor substrate by taking the patterned hard mask layer as a mask to form a plurality of holes along the third openings; and forming a transistor in the semiconductor substrate, and forming a capacitor in one of the holes.

### BRIEF DESCRIPTION OF DRAWINGS

One or more embodiments are exemplarily described by a figure in the corresponding accompanying drawings, and these exemplary descriptions do not constitute a limitation to the embodiments. The elements with a same reference sign in the accompanying drawings represent similar elements. Unless otherwise specified, the figures in the accompanying drawings do not constitute a scale limitation.

FIG. 1 is a schematic flowchart of a semiconductor structure manufacturing method according to a first embodiment of the present application;

FIG. 2 is a schematic diagram of a first exposure area according to a first embodiment of the present application;

FIG. 3 is a schematic diagram of a second exposure area according to a first embodiment of the present application;

FIG. 4 is a schematic top view of a patterned photoresist layer according to a first embodiment of the present application;

FIG. 5 is a schematic diagram of a structure as formed after manufacturing a photoresist film according to a first embodiment of the present application;

FIG. 6 is a schematic diagram of a structure as formed after performing exposure and development twice according to a first embodiment of the present application;

FIG. 7 is a schematic diagram of a structure as formed after etching a hard mask according to a first embodiment of the present application;

FIG. 8 is a schematic diagram of a structure as formed after etching a semiconductor substrate according to a first embodiment of the present application;

FIG. 9 is a schematic flowchart of a semiconductor structure manufacturing method according to a second embodiment of the present application;

FIG. 10 is a schematic diagram of a structure as formed after manufacturing a cross-linking layer according to a second embodiment of the present application;

FIG. 11 is a schematic top view of a cross-linking layer according to a second embodiment of the present application; and

FIG. 12 is a schematic structural diagram of a semiconductor substrate according to a third embodiment of the present application.

### DESCRIPTION OF EMBODIMENTS

In order to make the object, technical solutions and advantages of the embodiments of the present application clearer, respective embodiments of the present application will be described in detail below with reference to the accompanying drawings. However, it will be apparent to those skilled in the art that a number of technical details are presented in respective embodiments of the present application to provide the reader with a better understanding of the present application. However, the technical solutions claimed in the present application may be implemented without these technical details and various changes and modifications based on the following respective embodiments.

A first embodiment of the present application relates to a semiconductor structure manufacturing method, and the core idea of this embodiment is to form a patterned photoresist layer having a large number of first openings and second openings by performing exposure and development twice. Afterwards, the first openings and the second openings of the patterned photoresist layer are transferred to a hard mask to form a patterned hard mask layer having a plurality of third openings. That is, the patterned hard mask layer can be acquired by transferring the hard mask once, and then a large number of holes can be formed on the semiconductor substrate by taking the patterned hard mask layer as a mask. Thus, compared with the solution of transferring the hard mask twice in the related art, the present application can reduce steps of the manufacturing process and improve the efficiency in manufacturing the holes. In addition, the present application can prevent the occurrence of large process errors and generation of excessive by-products as caused by a larger number of times of hard mask transferring, thereby improving the quality of holes as manufactured.

The implementation details of the semiconductor structure manufacturing method according to this embodiment will be described in detail below. The following contents are merely intended to facilitate understanding of the provided implementation details, and are not necessary to implement the solution.

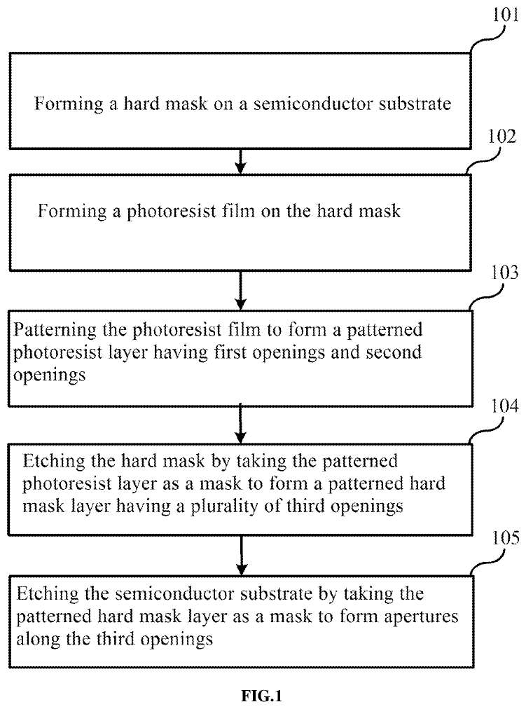

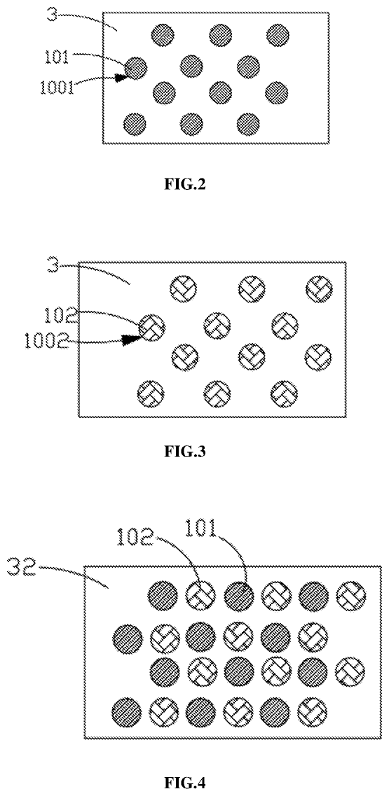

The schematic flowchart of the semiconductor structure manufacturing method in this embodiment is as shown in FIG. 1 and will be described in detail below with reference to FIGS. 2 to 9.

Step 101: forming a hard mask 2 on a semiconductor substrate 1.

Step 102: forming a photoresist film 3 on the hard mask 2.

The semiconductor substrate 1 may be a single-layer semiconductor material layer, such as a silicon material layer, or may be a laminated material layer formed by stacking layers of materials, such as a material layer constituting a certain semiconductor device structure. The holes 10 as formed on the semiconductor substrate 1 may be subsequently applied for manufacturing a semiconductor device, such as a dynamic random access memory (DRAM) or a static random access memory (SRAM).

The hard mask 2 is mainly applied in the photolithography process, during which a photoresist pattern is firstly transferred to the hard mask 2 and then a final pattern is etched and transferred to the semiconductor substrate 1 via the hard mask 2. The material of the hard mask 2 may generally be silicon oxynitride (SiON), silicon nitride (SiN), silicon dioxide (SiO₂) and the like, and the hard mask 2 may be formed by a chemical vapor deposition (CVD) process.

Step 103: patterning the photoresist film 3 to form a patterned photoresist layer 32 having a plurality of first openings 101 and second openings 102.

As shown in FIGS. 2 to 6, patterning the photoresist film 3 comprises: performing a first exposure on the photoresist film 3 to form a first exposure area, and developing the first exposure area to enable the first exposure area to have a plurality of first openings 101; and performing a second exposure on the photoresist film 3 on which the first exposure has been performed to form a second exposure area, and developing the second exposure area to enable the second exposure area to have a plurality of second openings 102.

As shown in FIG. 2, the first exposure is performed on the photoresist film 3 to form the first exposure area, and the first exposure area is developed to enable the first exposure area to have the plurality of first openings 101. The first exposure area comprises first hole-shape patterns 1001 that correspond to the first openings 101. As shown in FIG. 3, the second exposure is performed on the photoresist film 3 on which the first exposure has been performed to form the second exposure area, and the second exposure area is developed to enable the second exposure area to have the plurality of second openings 102. The second exposure area comprises a plurality of second hole-shape patterns 1002 that correspond to the second openings 102, and the second openings 102 are disposed at intervals among the first openings 101. In this embodiment, the first hole-shape patterns 1001 and the second hole-shape patterns 1002 are both shown in circles. However, those skilled in the art may understand that the first hole-shape patterns 1001 and the second hole-shape patterns 1002 may also have other shapes, such as square, ellipse, rhombus, and so on. In this embodiment, the first hole-shape patterns 1001 and the second hole-shape patterns 1002 may be initiatively configured to have a same or different shape according to actual needs.

As shown in FIG. 4, the first exposure area and the second exposure area are formed after performing exposure and development twice, and also a patterned photoresist layer 32 having first openings 101 and second openings 102 is formed. FIG. 4 is a schematic top view of the patterned photoresist layer 32. As shown, the second openings 102 in the second exposure area are disposed at intervals among the first openings 101 in the first exposure area, such that the first openings 101 in the first exposure area and the second openings 102 in the second exposure area do not intersect or overlap each other, thereby causing the first openings 101 and the second openings 102 on the patterned photoresist layer 32 to distribute more tightly.

Step 104: etching the hard mask 2 by taking the patterned photoresist layer 32 as a mask to form a patterned hard mask layer 21 having a plurality of third openings 103.

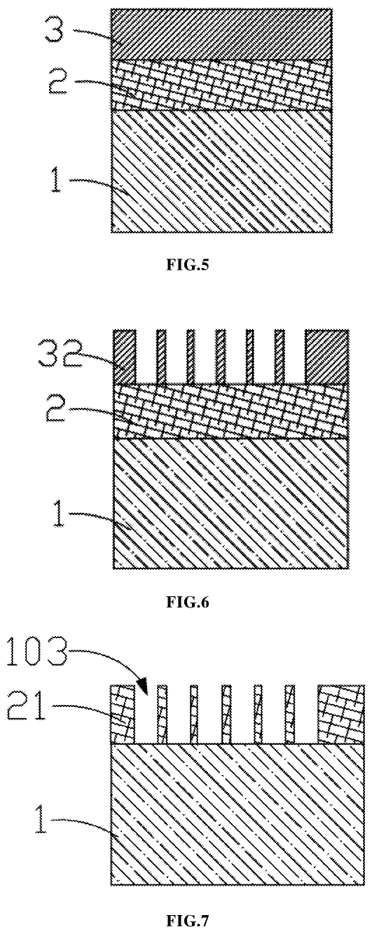

After forming the patterned photoresist layer 32 as shown in FIG. 4, the hard mask 2 is etched by taking the patterned photoresist layer 32 as a mask to form a patterned hard mask layer 21 having a plurality of third openings 103, as shown in FIG. 7. Then, the patterned photoresist layer 32 is removed to acquire the structure shown in FIG. 7. The third openings 103 therein correspond to the first openings 101 and the second openings 102in positions and number.

Step 105: etching the semiconductor substrate 1 by taking the patterned hard mask layer 21 as a mask to form holes 10 along the third openings 103.

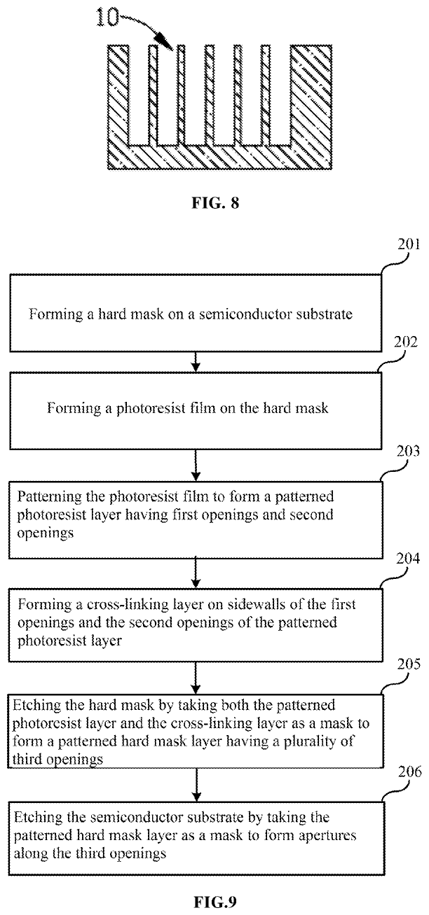

As shown in FIG. 9, the semiconductor substrate 1 is etched by taking the patterned hard mask layer 21 as a mask to form the holes 10 along the third openings 103. Then, the patterned hard mask layer 21 is removed to acquire the structure shown in FIG. 8, and this structure may be applied for manufacturing a semiconductor device, such as a dynamic random access memory (DRAM) or a static random access memory (SRAM). The third openings 103 are transferred to the semiconductor substrate 1 by the hard mask 2, such that influences of uneven edges of the third openings 103 of the patterned photoresist layer 32 on manufacturing of the holes 10 can be reduced.

Performing the first exposure on the photoresist film 3 to form the first exposure area comprises performing the first exposure on the photoresist film 3 by a preset photomask to form the first exposure area. The first exposure area comprises a plurality of first hole-shape patterns 1001 that correspond to the first openings 101. Performing the second exposure on the photoresist film 3 on which the first exposure has been performed to form the second exposure area comprises: changing a projection position of the preset photomask on the semiconductor substrate 1, and performing the second exposure on the photoresist film on which the first exposure has been performed by the preset photomask whose projection position has been changed to form the second exposure area. The second exposure area comprises a plurality of second hole-shape patterns 1002 that correspond to the second openings 102.

In this embodiment, the photoresist film 3 is exposed by the preset photomask to form the first exposure area while performing the first exposure. The first exposure area comprises a plurality of first hole-shape patterns 1001 that correspond to the first openings 101, and the first hole-shape patterns 1001 are arranged in a manner as shown in FIG. 2, such that the first exposure area having a plurality of evenly distributed first openings 101 can be formed. In addition, the projection position of the preset photomask on the semiconductor substrate 1 is changed while performing the second exposure, so that the second exposure is performed by the preset photomask whose projection position has been changed. Since the second exposure adopts a same photomask as the first exposure, the first hole-shape patterns 1001 in the first exposure area and the second hole-shape patterns 1002 in the second exposure area are arranged in a same manner (as shown in FIG. 3), and the second hole-shape patterns 1002 in the second exposure area are disposed at intervals between the first hole-shape patterns 1001 in the first exposure area, such that a plurality of first openings 101 and second openings 102 that are distributed more tightly can be formed.

Optionally, prior to changing the projection position of the preset photomask on the semiconductor substrate 1, the method further comprises: determining a first center point and a second center point of two adjacent first hole-shape patterns 1001 in the first exposure area when the first exposure area is formed by performing the first exposure on the photoresist film 3 by the preset photomask. Changing the projection position of the preset photomask on the semiconductor substrate 1 comprises: moving the preset photomask by a first distance along a straight line where the first center point and the second center point are located, or moving the semiconductor substrate 1 by a second distance along the straight line where the first center point and the second center point are located. A projection length of the first distance on the photoresist film 3 is half of a distance between the first center point and the second center point, and the second distance is half of the distance between the first center point and the second center point.

Before performing the second exposure, the first center point and the second center point of two adjacent first hole-shape patterns 1001 in the first exposure area while performing the first exposure on the photoresist film 3 by the preset photomask to form the first exposure area are firstly determined, such that the preset photomask may be moved by a first distance along a straight line where the first center point and the second center point are located while changing the projection position of the preset photomask on the semiconductor substrate 1, or the semiconductor substrate 1 may be moved by a second distance along the straight line where the first center point and the second center point are located. A projection length of the first distance on the photoresist film 3 is half of a distance between the first center point and the second center point, and the second distance is half of the distance between the first center point and the second center point. As a result, the first hole-shape patterns 1001 and the second hole-shape patterns 1002 can be distributed evenly in a rather high tightness, which is thereby beneficial to form the first openings 101 and the second openings 102 in high uniformity and high density.

Optionally, the hole-shape patterns in the preset photomask have a same shape with the first hole-shape patterns 1001. Most of the holes 10 are capacitor holes, and most of the first hole-shape patterns 1001 are circular. Thus, most of the hole-shape patterns in the preset photomask are also circular. However, those skilled in the art may understand that the hole-shape patterns in the preset photomask may be in other shapes, such as square, ellipse, rhombus, and so on.

Optionally, the first hole-shape patterns 1001 that are circular have a diameter ranging from 70 nanometers to 90 nanometers, and a distance between center points of two adjacent first hole-shape patterns 1001 ranges from 150 nanometers to 180 nanometers. Under this configuration, the second exposure is performed after moving the preset mask, and the first openings 101 and the second openings 102 as formed on the surface of the patterned photoresist layer 32 are as shown in FIG. 4. A distance between center points of the first openings 101 and the second openings 102 that are adjacent ranges from 70 nanometers to 100 nanometers, and a distance among the first openings 101 and the second openings 102 that are adjacent ranges from 5 nanometers to 20 nanometers.

In this embodiment, the first hole-shape patterns 1001 and the second hole-shape patterns 1002 are formed in a high density by performing the exposure twice rather than performing the exposure once, because forming hole-shape patterns in the photomask with a high density requires the exposure process capacity to be rather high and accurate, which is very difficult and prone to errors. Therefore, the exposure is performed twice in this embodiment by a photomask having hole-shape patterns in a low density, which can reduce the exposure errors while forming the hole-shape patterns in a high density.

Compared with the related art, a patterned photoresist layer 32 having a large number of first openings 101 and second openings 102 is formed by performing the exposure and development twice according to the embodiments of the present application. Afterwards, the first openings 101 and the second openings 102 of the patterned photoresist layer 32 are transferred to the hard mask 2 to form a patterned hard mask layer 21 having a plurality of third openings 103. That is, the patterned hard mask layer 21 can be acquired by transferring the hard mask once, and then a large number of holes 10 can be formed on the semiconductor substrate by taking the patterned hard mask layer 21 as a mask. Thus, compared with the solution of transferring the hard mask twice in the related art, the present application can reduce steps of the manufacturing process and improve the efficiency in manufacturing the holes 10. In addition, the present application can prevent the occurrence of large process errors and generation of excessive by-products as caused by a larger number of times of hard mask transferring, thereby improving the quality of holes 10 as manufactured.

A second embodiment of the present disclosure relates to a semiconductor structure manufacturing method. The second embodiment is an improvement based on the first embodiment, and the improvement mainly lies in that a cross-linking layer is formed on sidewalls of the first openings and the second openings of the patterned photoresist layer, and the hard mask layer is then etched by taking both the patterned photoresist layer and the cross-linking layer as a mask. As a result, the third openings as formed on the patterned hard mask layer have a smaller size than the first openings and the second openings on the patterned photoresist layer, which facilitates manufacturing and distribution of fine-sized holes.

The schematic flowchart of the semiconductor structure manufacturing method in this embodiment is as shown in FIG. 9 and will be described in detail below with reference to FIGS. 2 to 8 and FIGS. 10 to 11 in the first embodiment.

Step 201: forming a hard mask 2 on a semiconductor substrate 1.

Step 202: forming a photoresist film 3 on the hard mask 2.

Step 203: patterning the photoresist film 3 to form a patterned photoresist layer 32 having a plurality of first openings 101 and a plurality of second openings 102.

The aforesaid steps 201 to 203 are substantially the same as steps 101 to 103 in the first embodiment and will not be described again in this embodiment to avoid repetition.

Step 204: forming a cross-linking layer 4 on sidewalls of the first openings 101 and the second openings 102 of the patterned photoresist layer 32.

Step 205: etching the hard mask 2 by taking the patterned photoresist layer 32 and the cross-linking layer 4 as a mask to form a patterned hard mask layer 21 having a plurality of third openings 103.

Forming the cross-linking layer 4 on sidewalls of the first openings 101 and the second openings 102 of the patterned photoresist layer 32 comprises: coating methacrylic resin on the sidewalls of the first openings 101 and the second openings 102 of the patterned photoresist layer 32; and baking the patterned photoresist layer 32 coated with the methacrylic resin to enable part of the patterned photoresist layer 32 to react with the methacrylic resin, thereby forming the cross-linking layer 4 on the sidewalls of the first openings 101 and the second openings 102.

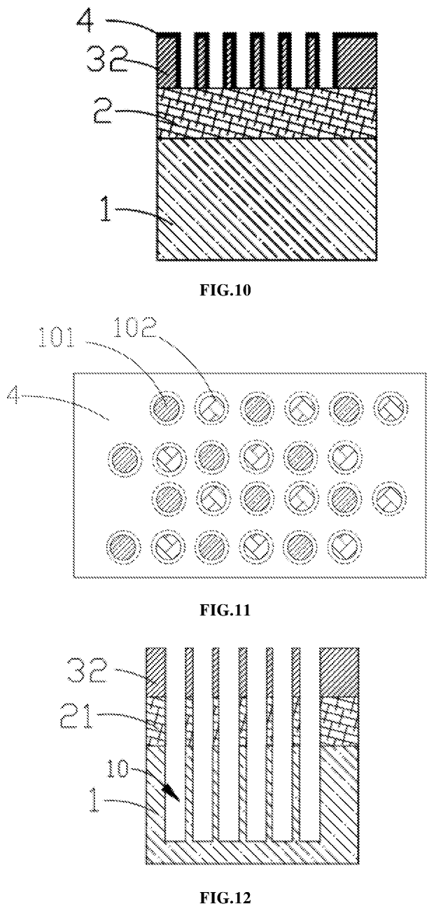

A critical size of holes or grooves may be reduced by a resolution enhancement lithography assisted by chemical shrink (RELACS) reagent. A basic principle of this method is that polymer and cross-linking molecules in the RELACS reagent may undergo a cross-linking reaction under the action of photoacid present on the surface of the patterned photoresist layer 32. As shown in FIG. 10, this cross-linking reaction forms a cross-linking layer 4 on the surface of the patterned photoresist layer 32 and the sidewalls of the first openings 101 and the second openings 102 of the patterned photoresist layer 32 to increase the width of the photoresist pattern. Since the first openings 101 and the second openings 102 are formed by etching the material between adjacent photoresists, the increase in the width of the photoresist pattern indicates a shrink in sizes of the first openings 101 and the second openings 102. FIG. 11 is a schematic top view of the cross-linking layer 4, in which the first openings 101 and the second openings 102 before the shrink are shown in dashed lines, and the first openings 101 and the second openings 102 after the shrink are shown in solid lines. Assuming that the first openings 101 and the second openings 102 before the shrink have a diameter ranging from 70 nanometers and 90 nanometers and a thickness of the cross-linking layer 4 (i.e., the shrink size) ranges from 5 nanometers to 20 nanometers, then the first openings 101 and the second openings 102 after the shrink may have a diameter ranging from 50 nanometers to 85 nanometers.

Step 206: etching the semiconductor substrate 1 by taking the patterned hard mask layer as a mask to form a plurality of holes 10 along the third openings 103.

As a result, the hard mask 2 is etched by taking both the patterned photoresist layer 32 and the cross-linking layer 4 as a mask, and the third openings 103 as formed on the patterned hard mask layer 21 can thereby have a smaller diameter than the first openings 101 or the second openings 102 on the patterned photoresist layer 32, which is beneficial to manufacture fine-sized holes 10 on the semiconductor substrate.

Compared with the related art, a cross-linking layer 4 is formed on the sidewalls of the first openings 101 and the second openings 102 of the patterned photoresist layer 32, and then the hard mask 2 is etched by taking both the patterned photoresist layer 32 and the cross-linking layer 4 as a mask, in the embodiments of the present application. As a result, the third openings 103 as formed on the patterned hard mask layer 21 can have a smaller diameter than the first openings 101 or the second openings 102 on the patterned photoresist layer 32, which is beneficial to manufacture fine-sized holes 10.

The steps of the respective methods are divided only for clarity of the description. During the implementation, the steps may be combined as one step or some steps may be split into a plurality of steps, and the steps all fall into the protection scope of the present patent as long as they comprise a same logical relationship. In addition, it also falls into the protection scope of the present patent to add insignificant modifications or designs to the algorithm or procedure without changing the core design of the algorithm and process.

The third embodiment of the present application relates to a semiconductor structure, which is formed by the semiconductor structure manufacturing method according to the first embodiment or the second embodiment, which as shown in FIG. 12 comprises a semiconductor substrate 1, a patterned hard mask layer 21, and a patterned photoresist layer 32 stacked in sequence. Referring to FIGS. 2 to 9 of the first embodiment, the patterned photoresist layer 32 has first openings 101 and second openings 102, and is configured to form third openings of a patterned hard mask layer 21. The third openings 103 correspond to the first openings 101 and the second openings 102. The first openings 101 and the second openings 102 are formed by performing exposure and development twice, and the second openings 102 are disposed at intervals among the first openings 101. The patterned hard mask layer 21 is configured to form holes 10 of the semiconductor substrate 1, and the holes 10 correspond to the third openings 103.

Specifically, the photoresist film 3 is exposed by the preset photomask while performing the first exposure to thereby form the first exposure area. The first exposure area comprises a plurality of first hole-shape patterns 1001 that correspond to the first openings 101, and the first hole-shape patterns 1001 are arranged in a manner as shown in FIG. 2 of the first embodiment, such that the first exposure area having a plurality of evenly distributed first openings 101 can be formed. In addition, the projection position of the preset photomask on the semiconductor substrate 1 is changed while performing the second exposure, such that the second exposure is performed by the preset photomask whose projection position has been changed. Since the second exposure adopts a same photomask as the first exposure, the first hole-shape patterns 1001 in the first exposure area and the second hole-shape patterns 1002 in the second exposure area are arranged in a same manner (as shown in FIG. 3 of the first embodiment), and the second hole-shape patterns 1002 in the second exposure area are disposed at intervals between the first hole-shape patterns 1001 in the first exposure area, such that a plurality of first openings 101 and second openings 102 that are distributed more tightly can be formed.

Before performing the second exposure, the first center point and the second center point of two adjacent first hole-shape patterns 1001 in the first exposure area while performing the first exposure on the photoresist film 3 by the preset photomask to form the first exposure area are firstly determined, such that the preset photomask may be moved by a first distance along a straight line where the first center point and the second center point are located while changing the projection position of the preset photomask on the semiconductor substrate 1, or the semiconductor substrate 1 may be moved by a second distance along the straight line where the first center point and the second center point are located. A projection length of the first distance on the photoresist film 3 is half of a distance between the first center point and the second center point, and the second distance is half of the distance between the first center point and the second center point. As a result, the first hole-shape patterns 1001 and the second hole-shape patterns 1002 can be distributed evenly in a rather high tightness, which is thereby beneficial to form the first openings 101 and the second openings 102 in high uniformity and high density.

In this embodiment, the first hole-shape patterns 1001 and the second hole-shape patterns 1002 are formed in a high density by performing the exposure twice rather than performing the exposure once, because forming hole-shape patterns in the photomask with a high density requires the exposure process capacity to be rather high and accurate, which is very difficult and prone to errors. Therefore, the exposure is performed twice by a photomask having hole-shape patterns in a low density in this embodiment, which can reduce the exposure errors while forming the hole-shape patterns in a high density.

In the embodiment of the present application, while manufacturing the semiconductor structure, the patterned photoresist layer 32 having a large number of first openings 101 and second openings 102 is formed by performing the exposure and development twice. Afterwards, the first openings 101 and the second openings 102 of the patterned photoresist layer 32 are transferred to the hard mask 2 to form a patterned hard mask layer 21 having a plurality of third openings 103. That is, the patterned hard mask layer 21 can be acquired by transferring the hard mask once, and then a large number of holes 10 can be formed on the semiconductor substrate by taking the patterned hard mask layer 21 as a mask. Thus, compared with the solution of transferring the hard mask twice in the related art, the present application can reduce steps of the manufacturing process and improve the efficiency in manufacturing the holes 10. In addition, the present application can prevent the occurrence of large process errors and generation of excessive by-products as caused by a larger number of times of hard mask transferring, thereby improving the quality of holes 10 as manufactured.

Optionally, the first openings 101 have the same size and shape with the second openings 102, and the first openings 101 are circular.

Optionally, a distance between center points of the first openings 101 and the second openings 102 that are adjacent ranges from 70 nanometers to 100 nanometers, and a distance among the first openings 101 and the second openings 102 that are adjacent ranges from 5 nanometers to 20 nanometers.

Optionally, as shown in FIGS. 10 and 11 of the first embodiment, the semiconductor structure further comprises a cross-linking layer 4 on the sidewalls of the first openings 101 and the second openings 102 in the patterned photoresist layer 32. The patterned photoresist layer 32 and the cross-linking layer 4 are both used to form the third openings 103 of the patterned hard mask layer 21, and the third openings 103 have a smaller diameter than the first openings 101 or the second openings 102.

A critical size of holes or grooves may be reduced by a resolution enhancement lithography assisted by chemical shrink (RELACS) reagent. A basic principle of this method is that polymer and cross-linking molecules in the RELACS reagent may undergo a cross-linking reaction under the action of photoacid present on the surface of the patterned photoresist layer 32. As shown in FIG. 10, this cross-linking reaction forms a cross-linking layer 4 on the surface of the patterned photoresist layer 32 and the sidewalls of the first openings 101 and the second openings 102 of the patterned photoresist layer 32 to increase the width of the photoresist pattern. Since the first openings 101 and the second openings 102 are formed by etching the material between adjacent photoresists, the increase in the width of the photoresist pattern indicates a shrink in sizes of the first openings 101 and the second openings 102. FIG. 11 is a schematic top view of the cross-linking layer 4, in which the first openings 101 and the second openings 102 before the shrink are shown in dashed lines, and the first openings 101 and the second openings 102 after the shrink are shown in solid lines. Assuming that the first openings 101 and the second openings 102 before the shrink have a diameter ranging from 70 nanometers and 90 nanometers and a thickness of the cross-linking layer 4 (i.e., the shrink size) ranges from 5 nanometers to 20 nanometers, then the first openings 101 and the second openings 102 after the shrink may have a diameter ranging from 50 nanometers to 85 nanometers.

As a result, the hard mask 2 is etched by taking both the patterned photoresist layer 32 and the cross-linking layer 4 as a mask, and the third openings 103 as formed on the patterned hard mask layer 21 can thereby have a smaller diameter than the first openings 101 or the second openings 102 on the patterned photoresist layer 32, which is beneficial to manufacture fine-sized holes 10 on the semiconductor substrate.

A third embodiment of the present application is formed by adopting the aforesaid semiconductor structure manufacturing method according to the first embodiment or the second embodiment. Therefore, the implementation details of the manufacturing method according to the first embodiment or the second embodiment may be applied to this embodiment, and will not be described again in this embodiment to avoid repetition.

A fourth embodiment of the present application relates to a memory manufacturing method, which comprises the semiconductor structure manufacturing method according to the first embodiment or the second embodiment. In addition, after step 105 (etching the semiconductor substrate 1 by taking the patterned hard mask layer 21 as a mask to form holes 10 along the third openings 103) in the first embodiment, or after step 206 (etching the semiconductor substrate 1 by taking the patterned hard mask layer as a mask to form holes 10 along the third openings 103) in the second embodiment, the memory manufacturing method further comprises forming a transistor in the semiconductor substrate, and forming a capacitor in one of the holes.

The forth embodiment of the present application comprises the semiconductor structure manufacturing method according to the first embodiment or the second embodiment. Therefore, the implementation details of the manufacturing method according to the first embodiment or the second embodiment may be applied to this embodiment, and will not be described again in this embodiment to avoid repetition.

A person of ordinary skill in the art may understand that the above embodiments are specific embodiments for implementing the present application, and in practice, various formal or detail changes may be made without departing from the spirit and scope of the present application.

What is claimed is:

1. A semiconductor structure manufacturing method, comprising:
forming a hard mask on a semiconductor substrate;
forming a photoresist film on the hard mask;
patterning the photoresist film to form a patterned photoresist layer having a plurality of first openings and a plurality of second openings, wherein the second openings are disposed at intervals among the first openings;
wherein patterning the photoresist film comprises: performing a first exposure to form a first exposure area on the photoresist film, and developing the first exposure area to enable the first exposure area to have a plurality of the first openings; and
performing a second exposure to form a second exposure area on the photoresist film on which the first exposure has been performed, and developing the second exposure area to enable the second exposure area to have a plurality of the second openings;
etching the hard mask by taking the patterned photoresist layer as a mask to form a patterned hard mask layer having a plurality of third openings, wherein the third openings correspond to the first openings and the second openings; and
etching the semiconductor substrate by taking the patterned hard mask layer as a mask to form a plurality of holes along the third openings.

2. The semiconductor structure manufacturing method according to claim 1,
wherein performing the first exposure on the photoresist film to form the first exposure area comprises performing the first exposure on the photoresist film by a preset photomask to form the first exposure area, wherein the first exposure area comprises a plurality of first hole-shape patterns that correspond to the first openings; and
performing the second exposure on the photoresist film on which the first exposure has been performed to form the second exposure area comprises: changing a projection position of the preset photomask on the semiconductor substrate; and performing the second exposure on the photoresist film on which the first exposure has been performed by the preset photomask whose projection position has been changed to form the second exposure area, wherein the second exposure area comprises a plurality of second hole-shape patterns that correspond to the second openings.

3. The semiconductor structure manufacturing method according to claim 2, wherein prior to changing the projection position of the preset photomask on the semiconductor substrate, the method further comprises:
fixing a first center point and a second center point of two adjacent ones of the first hole-shape patterns in the first exposure area when the first exposure area is formed by performing the first exposure on the photoresist film by the preset photomask;
changing the projection position of the preset photomask on the semiconductor substrate comprises:
moving the preset photomask by a first distance along a straight line where the first center point and the second center point are located, wherein a length of the first distance's projection on the photoresist film is half of a length of a distance between the first center point and the second center point; or
moving the semiconductor substrate by a second distance along the straight line where the first center point and the second center point are located, wherein a length of the second distance is half of a length of the distance between the first center point and the second center point.

4. The semiconductor structure manufacturing method according to claim 2, wherein each one of the first hole-shape patterns is circular.

5. The semiconductor structure manufacturing method according to claim 4, wherein each one of the first hole-shape patterns being circular has a diameter ranging from 70 nanometers to 90 nanometers, and a length of a distance between a first center point and a second center point of two adjacent ones of the first hole-shape patterns ranges from 150 nanometers to 180 nanometers.

6. The semiconductor structure manufacturing method according to claim 1, wherein etching the hard mask by taking the patterned photoresist layer as the mask to form the patterned hard mask layer having the plurality of third openings comprises:
forming a cross-linking layer on sidewalls both of the first openings and the second openings of the patterned photoresist layer; and
etching the hard mask by taking both the patterned photoresist layer and the cross-linking layer as the mask to form the patterned hard mask layer having the plurality of the third openings, wherein each one of the third openings has a smaller diameter than each one of the first openings or the second openings.

7. The semiconductor structure manufacturing method according to claim 6, wherein the cross-linking layer has a thickness ranging from 5 nanometers to 20 nanometers.

8. The semiconductor structure manufacturing method according to claim 6, wherein forming the cross-linking layer on the sidewalls of the first openings and the second openings of the patterned photoresist layer comprises:
coating methacrylic resin on the sidewalls both of the first openings and the second openings of the patterned photoresist layer; and
baking the patterned photoresist layer coated with the methacrylic resin to enable part of the patterned photoresist layer to react with the methacrylic resin, thereby forming the cross-linking layer on the sidewalls both of the first openings and the second openings.

9. A semiconductor structure, comprising: a semiconductor substrate, a patterned hard mask layer, and a patterned photoresist layer stacked in sequence, wherein
the patterned photoresist layer has first openings and second openings and is configured to form third openings of the patterned hard mask layer, wherein the third openings correspond to the first openings and the second openings, the first openings and the second openings are formed by performing exposure and development twice, and the second openings are disposed at intervals between the first openings; and
the patterned hard mask layer is configured to form holes on the semiconductor substrate, wherein the holes correspond to the third openings.

10. The semiconductor structure according to claim 9, wherein each one of the first openings has a same shape and size with each one of the second openings, and each one of the first openings is circular.

11. The semiconductor structure according to claim 9, wherein a distance between a center point of one of the first openings and a center point of one of the second openings that is adjacent to the one of the first openings ranges from 70 nanometers to 100 nanometers, and a length of a distance between one of the first openings and one of the second openings that is adjacent to the one of the first openings ranges from 5 nanometers to 20 nanometers.

12. The semiconductor structure according to claim 9, further comprising: a cross-linking layer on sidewalls both of the first openings and the second openings in the patterned photoresist layer; and
the patterned photoresist layer and the cross-linking layer are both used to form the third openings on the patterned hard mask layer, wherein each one of the third openings has a smaller diameter than each one of the first openings or the second openings.

13. The semiconductor structure according to claim 12, wherein the cross-linking layer has a thickness ranging from 5 nanometers to 20 nanometers.

14. A memory manufacturing method, comprising:
forming a hard mask on a semiconductor substrate;
forming a photoresist film on the hard mask;
patterning the photoresist film to form a patterned photoresist layer having a plurality of first openings and a plurality of second openings, wherein the second openings are disposed at intervals among the first openings;
wherein patterning the photoresist film comprises: performing a first exposure to form a first exposure area on the photoresist film, and developing the first exposure area to enable the first exposure area to have a plurality of the first openings;
and performing a second exposure to form a second exposure area on the photoresist film on which the first exposure has been performed, and developing the second exposure area to enable the second exposure area to have a plurality of the second openings;
etching the hard mask by taking the patterned photoresist layer as a mask to form a patterned hard mask layer having a plurality of third openings, wherein the third openings correspond to the first openings and the second openings;
etching the semiconductor substrate by taking the patterned hard mask layer as a mask to form a plurality of holes along the third openings; and
forming a transistor in the semiconductor substrate, and forming a capacitor in one of the holes.

15. The memory manufacturing method according to claim 14, wherein performing the first exposure on the photoresist film to form the first exposure area comprises performing the first exposure on the photoresist film by a preset photomask to form the first exposure area, wherein the first exposure area comprises a plurality of first hole-shape patterns that correspond to the first openings; and
performing the second exposure on the photoresist film on which the first exposure has been performed to form the second exposure area comprises: changing a projection position of the preset photomask on the semiconductor substrate; and performing the second exposure on the photoresist film on which the first exposure has been performed by the preset photomask whose projection position has been changed to form the second exposure area, wherein the second exposure area comprises a plurality of second hole-shape patterns that correspond to the second openings.

16. The memory manufacturing method according to claim 15, wherein prior to changing the projection position of the preset photomask on the semiconductor substrate, the method further comprises:
fixing a first center point and a second center point of two adjacent ones of the first hole-shape patterns in the first exposure area when the first exposure area is formed by performing the first exposure on the photoresist film by the preset photomask;
changing the projection position of the preset photomask on the semiconductor substrate comprises:
moving the preset photomask by a first distance along a straight line where the first center point and the second center point are located, wherein a length of the first distance's projection on the photoresist film is half of a distance between the first center point and the second center point; or
moving the semiconductor substrate by a second distance along the straight line where the first center point and the second center point are located, wherein a length of the second distance is half of a length of the distance between the first center point and the second center point.

17. The memory manufacturing method according to claim 15, wherein each one of the first hole-shape patterns is circular.

18. The memory manufacturing method according to claim 17, wherein each one of the first hole-shape patterns being circular has a diameter ranging from 70 nanometers to 90 nanometers, and a length of a distance between a first center points and a second center point of two adjacent ones of the first hole-shape patterns ranges from 150 nanometers to 180 nanometers.

19. The memory manufacturing method according to claim 14, wherein etching the hard mask by taking the patterned photoresist layer as the mask to form the patterned hard mask layer having the plurality of third openings comprises:
forming a cross-linking layer on sidewalls both of the first openings and the second openings of the patterned photoresist layer; and
etching the hard mask by taking both the patterned photoresist layer and the cross-linking layer as the mask to form the patterned hard mask layer having the plurality of the third openings, wherein each one of the third openings has a smaller diameter than each one of the first openings or the second openings.

20. The memory manufacturing method according to claim 19, wherein forming the cross-linking layer on the sidewalls of the first openings and the second openings of the patterned photoresist layer comprises:
coating methacrylic resin on the sidewalls both of the first openings and the second openings of the patterned photoresist layer; and
baking the patterned photoresist layer coated with the methacrylic resin to enable part of the patterned photoresist layer to react with the methacrylic resin, thereby forming the cross-linking layer on the sidewalls both of the first openings and the second openings.
